(19) United States
(12) Patent Application Publication
(10) Pub. No.: US 2026/0314228 A1
(43) Pub. Date: Oct. 8, 2026

(54) ELASTIC MEMBER AND DISPLAY DEVICE COMPRISING SAME

(71) Applicant: LG INNOTEK CO., LTD., Seoul (KR)

(72) Inventors: Sung Won KANG, Seoul (KR); Joon Hyuk YANG, Seoul (KR); Jong Min LEE, Seoul (KR)

(21) Appl. No.: 19/476,795

(22) PCT Filed: May 3, 2024
(86) PCT No.: PCT/KR2024/006027

§ 371 Date: Oct. 20, 2025

(30) Foreign Application Priority Data
May 3, 2023 (KR) 10-2023-0058034

(51) Int. Cl. H10K 59/80; B32B 3/26; B32B 27/06; H10K 102/00

(52) U.S. Cl. CPC H10K 59/80; B32B 3/266; B32B 27/06; B32B 2260/021; B32B 2260/046; B32B 2457/206; H10K 2102/311

(57) ABSTRACT

An embodiment provides an elastic member foldable with respect a folding axis, the elastic member comprising: a first layer including a first base material and a first fiber disposed in the first base material; and a second layer disposed under the first layer and including a second base material and a second fiber disposed in the second base material, wherein the first fiber extends in the first base material at an angle of 80° to 100° with respect to the folding axis, wherein the second fiber extends in a direction different from a direction in which the first fiber extends, and wherein the second layer includes a pattern part with a hole shape.

### TECHNICAL FIELD

An embodiment relates to an elastic member and a display device including the same.

### BACKGROUND ART

Recently, demand for foldable display devices that are easy to carry and may display images on a large screen is increasing.

The foldable display device is carried in a folded state and displays an image in an unfolded state. Accordingly, it is possible to facilitate the user's portability while increasing an image region.

The foldable display device can be folded and unfolded repeatedly. Accordingly, the foldable display device include an elastic member that can bend in one direction.

Recently, a carbon fiber reinforced plastic (CFRP) or a glass fiber reinforced plastic (GFRP) have been used as the elastic member. The CFRP and the GFRP may be easily folded because they have a small modulus. However, CFRP and GFRP have low strength, so they are not used alone but in combination with metal plates.

Accordingly, there is a problem in that a thickness of the elastic member increases.

Therefore, a new structure of elastic member capable of solving the above problems is required.

Meanwhile, Korean Patent Publication No. KR 10-2018-0079091 (Jul. 10, 2018) is disclosed as a prior art related to elastic members.

### DISCLOSURE

### Technical Problem

An embodiment provides an elastic member with improved strength.

The embodiment provides an elastic member having a small thickness.

### technical Solution

An embodiment provides an elastic member foldable with respect a folding axis, the elastic member comprising: a first layer including a first base material and a first fiber disposed in the first base material; and a second layer disposed under the first layer and including a second base material and a second fiber disposed in the second base material, wherein the first fiber extends in the first base material at an angle of 80° to 100° with respect to the folding axis, wherein the second fiber extends in a direction different from a direction in which the first fiber extends, and wherein the second layer includes a pattern part with a hole shape.

In addition, the second fiber extends while having an angle of 0° to 10° or an angle in a diagonal direction with respect to the folding axis.

In addition, the second fiber includes a plurality of fibers extending in intersecting directions.

In addition, the first fiber and the second fiber extend in intersecting directions.

In addition, the elastic member includes a first region adjacent to the folding axis and a second region disposed further from the folding axis than the first region, and the pattern part is provided in the first region.

In addition, the pattern part partially penetrates the first layer.

In addition, a thickness of the first layer is smaller than a thickness of the second layer.

In addition, the elastic member further comprises a third layer disposed on of the first layer, wherein the third layer includes a third base material and a third fiber provided in the third base material, the third fiber extends in a direction different from the direction in which the first fiber extends, and the third layer includes a pattern part with a hole-shape.

In addition, the second fiber and the third fiber extend while having an angle of 0° to 10° or an angle in a diagonal direction with respect to the folding axis.

In addition, the second fiber and the third fiber extend in different directions.

In addition, at least one of the second fiber and the third fiber includes a plurality of fibers extending in intersecting directions.

In addition, the pattern part of the second layer and the pattern part of the third layer are formed in the first region.

In addition, at least one of the pattern part of the second layer and the pattern part of the third layer partially penetrates the first layer.

In addition, the pattern part of the second layer and the pattern part of the third layer do not overlap in a thickness direction of the first layer.

In addition, the pattern part of the second layer and the pattern part of the third layer have different sizes.

### Advantageous Effects

An elastic member according to a first embodiment includes a first layer and a second layer. The first layer includes a first fiber, and the second layer includes a second fiber.

The first fiber and the second fiber extend in different directions. Therefore, the first fiber and the second fiber are disposed in an intersecting manner. This enhances the strength of the elastic member. Accordingly, the folding reliability of the elastic member is improved. When the elastic member is folded and then unfolded, stress can be transmitted to a second region. Accordingly, a shape of the second region can be changed. The elastic member according to the first embodiment includes fibers extending in different directions. Therefore, a shape of the second region can be prevented from changing due to the stress. Therefore, the elastic member according to the first embodiment has improved folding reliability.

Furthermore, fibers extending in a direction different from a direction in which the folding axis extends are cut. Specifically, the second fiber is cut at the first region. Therefore, the elastic member is easily folded at the first region. Therefore, the elastic member according to the first embodiment has improved folding characteristics.

The elastic member according to the second embodiment includes a first layer, a second layer, and a third layer. The first layer includes a first fiber, the second layer includes a second fiber, and the third layer includes a third fiber.

The first fiber extends in a different direction from the second fiber and the third fiber. Alternatively, the first fiber, the second fiber, and the third fiber extend in different directions.

Therefore, the first fiber, the second fiber, and the third fiber are disposed in an intersecting manner. This enhances the strength of the elastic member. Accordingly, the folding reliability of the elastic member is enhanced. When the elastic member is folded and then unfolded, stress can be transmitted to the second region. Accordingly, a shape of the second region can be changed. The elastic member according to the second embodiment includes fibers extending in different directions. Accordingly, the shape of the second region can be prevented from changing due to the stress. Therefore, the elastic member according to the second embodiment has improved folding reliability.

Furthermore, the fibers extending in a direction different from a direction in which the folding axis extends are cut. Specifically, the second fiber and the third fiber are cut in the first region. Therefore, the elastic member can be easily folded in the first region. Therefore, the elastic member according to the second embodiment has improved folding characteristics.

### DESCRIPTION OF DRAWINGS

FIG. 1 is a perspective view of a display device according to an embodiment.

FIG. 2 is a perspective view of an elastic member according to an embodiment.

FIG. 3 is a side view of an elastic member according to an embodiment before folding.

FIG. 4 is a side view of an elastic member according to an embodiment after folding.

FIG. 5 is a perspective view of an elastic member according to a first embodiment.

FIG. 6 is a perspective view of a first layer of an elastic member according to a first embodiment.

FIG. 7 is a photograph of a cross-sectional view taken along the B-B′ region of FIG. 6.

FIG. 8 is a top view of an elastic member according to a first embodiment.

FIGS. 9 and 10 are cross-sectional views taken along the A-A′ region of FIG. 5.

FIG. 11 (a) to (d) are drawings illustrating various arrangements of a second fiber.

FIGS. 12 to 18 are drawings illustrating patterns formed in a second layer of the elastic member.

FIG. 19 is a perspective view of an elastic member according to a second embodiment.

FIGS. 20 and 21 are top views of an elastic member according to a second embodiment.

FIGS. 22 to 25 are cross-sectional views taken along the C-C′ region of FIG. 19.

FIGS. 26 and 27 are cross-sectional views of a folding support including an elastic member according to an embodiment.

FIGS. 28 and 29 are cross-sectional views of a display device including a folding support according to an embodiment.

FIG. 30 is a drawing illustrating an application example of a display device according to an embodiment.

### MODES OF THE INVENTION

Hereinafter, embodiments of the present disclosure will be described in detail with reference to the accompanying drawings. However, the spirit and scope of the present disclosure is not limited to a part of the embodiments described, and may be implemented in various other forms, and within the spirit and scope of the present disclosure, one or more of the elements of the embodiments may be selectively combined and redisposed. In addition, unless expressly otherwise defined and described, the terms used in the embodiments of the present disclosure (including technical and scientific terms) may be construed the same meaning as commonly understood by one of ordinary skill in the art to which the present disclosure belongs, and the terms such as those defined in commonly used dictionaries may be interpreted as having a meaning that is consistent with their meaning in the context of the relevant art. In addition, the terms used in the embodiments of the present disclosure are for describing the embodiments and are not intended to limit the present disclosure.

In this specification, the singular forms may also include the plural forms unless specifically stated in the phrase, and may include at least one of all combinations that may be combined in A, B, and C when described in “at least one (or more) of A (and), B, and C”.

Further, in describing the elements of the embodiments of the present disclosure, the terms such as first, second, A, B, (a), and (b) may be used. These terms are only used to distinguish the elements from other elements, and the terms are not limited to the essence, order, or order of the elements.

In addition, when an element is described as being “connected”, “coupled”, or “contacted” to another element, it may include not only when the element is directly “connected” to, “coupled” to, or “contacted” to other elements, but also when the element is “connected”, “coupled”, or “contacted” by another element between the element and other elements.

In addition, when described as being formed or disposed “on (over)” or “under (below)” of each element, the “on (over)” or “under (below)” may include not only when two elements are directly connected to each other, but also when one or more other elements are formed or disposed between two elements.

Further, when expressed as “on (over)” or “under (below)”, it may include not only the upper direction but also the lower direction based on one element.

Hereinafter, an elastic member, a folding support and a display device including the elastic member according to an embodiment will be described with reference to drawings.

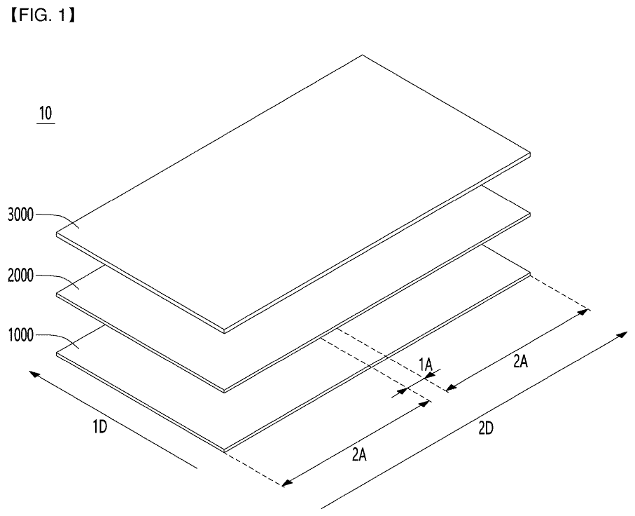

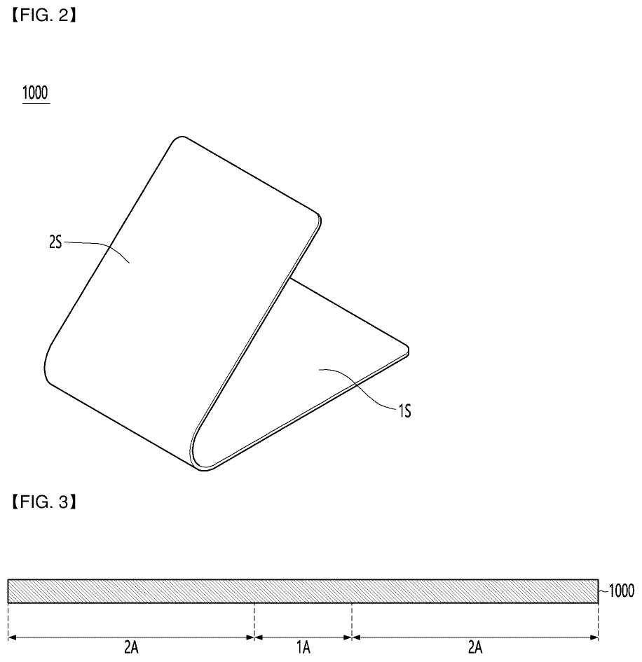

FIG. 1 is a perspective view of a display device. FIGS. 2 to 4 are perspective views and cross-sectional views of the elastic member.

Referring to FIG. 1, a display device 10 includes an elastic member 1000 and a panel. The panel may include at least one of a display panel 2000 and a touch panel 3000. For convenience of explanation, the panel will be described below as including the display panel 2000 and the touch panel 3000.

The elastic member 1000, the display panel 2000, and the touch panel 3000 may be bonded by an adhesive layer.

The elastic member 1000 supports the display panel 2000 and the touch panel 3000. The elastic member 1000 may be a supporting substrate supporting the display panel 2000 and the touch panel 3000.

The elastic member 1000 may include at least one of a metallic material and a non-metallic material. For example, the elastic member 1000 may include a non-metallic material.

The elastic member 1000 has elasticity. Accordingly, the elastic member 1000 may be bent in one direction. For example, the elastic member 1000 may be folded in one direction. That is, the elastic member 1000 may be a display substrate applied to a foldable display device.

The elastic member 1000 is defined in a first direction 1D and a second direction 2D. For example, the first direction 1D is defined as a same direction as a folding axis of the elastic member 1000. The second direction 2D is defined as a different direction from the first direction 1D. The second direction 2D is defined as a direction perpendicular to the first direction 1D.

Hereinafter, for convenience of explanation, the first direction 1D is defined as the same direction as the folding axis. Furthermore, the first direction 1D is defined as a width direction of the elastic member 1000. Furthermore, the second direction 2D is defined as a length direction of the elastic member 1000.

The elastic member 1000 may include at least two regions. For example, the elastic member 1000 may include a first region 1A and a second region 2A.

The first region 1A is defined as a region where the elastic member 1000 folds. In other words, the first region 1A is a folding region.

In addition, the second region 2A is defined as a region where the elastic member 1000 does not fold. In other words, the second region 2A is an unfolding region.

The display panel 2000 is disposed on the elastic member 1000.

The display panel 2000 may include a plurality of pixels, each including a switching thin film transistor, a driving thin film transistor, a capacitor, and an organic light emitting diode (OLED). The organic light emitting diode can be deposited at a relatively low temperature. Therefore, it has low power consumption and high brightness, making it suitable for use in foldable display devices. Here, a pixel refers to a minimum unit for displaying an image. The display panel displays an image through a plurality of pixels.

The display panel 2000 may include a substrate, a gate line disposed on the substrate, a data line and a common power line intersecting the gate line in an insulated manner. Generally, one pixel may be defined by a boundary between the gate line, the data line, and the common power line.

The substrate may include a flexible material, such as a plastic film. The display panel 2000 may be formed by arranging organic light-emitting diodes and pixel circuits on a flexible film.

The touch panel 3000 is disposed on the display panel 2000. The touch panel 3000 applies a touch function to the foldable display device. Alternatively, the touch panel may be omitted in a foldable display device that only displays images without the touch function.

The touch panel 3000 includes a substrate and touch electrodes disposed on the substrate. The touch electrodes can detect a position of an input device touching the foldable display device using a capacitive or resistive method.

The substrate of the touch panel 3000 may include a flexible material, such as a plastic film. The touch panel 3000 may be implemented by arranging touch electrodes on the flexible film.

The touch panel 3000 may be formed integrally with the display panel 2000. For example, the touch panel 3000 may be formed integrally with the display panel 2000 in an on-cell or in-cell manner. Accordingly, the substrate of the touch panel 3000 may be a substrate of the display panel or a component of the display panel. Accordingly, the touch panel 3000 and the display panel 2000 may be formed integrally. Consequently, a thickness of the foldable display device can be reduced.

The elastic member 1000 and the display panel 2000 may have different sizes.

For example, an area of the elastic member 1000 may be 90% or more and 110% or less of the area of the display panel 2000. Specifically, the area of the elastic member 1000 may be 95% or more and 105% or less of the area of the display panel 2000. More specifically, the area of the elastic member 1000 may be 97% or more and 100% or less of the area of the display panel 2000.

If the area of the elastic member 1000 is less than 90% of the area of the display panel 2000, a supporting force of the elastic member 1000 for supporting the display panel 2000 and the touch panel 3000 is reduced. Accordingly, curling may occur in the unfolding region of the elastic member 1000.

In addition, if the area of the elastic member 1000 exceeds 110% of the area of the display panel 2000, a bezel region of the foldable display device may increase.

Meanwhile, although not shown in the drawing, a foldable display device cover window may be additionally disposed above the touch panel 3000 or above the display panel 2000 (if the touch panel is omitted). The cover window may protect the foldable display device.

Referring to FIG. 2, the elastic member 1000 may be bent in one direction.

In detail, the elastic member 1000 may include a first surface 1S and a second surface 2S opposite the first surface 1S. The elastic member 1000 may be bent such that the first surface 1S or the second surface 2S faces each other. Accordingly, the elastic member 1000 can be bent so that a surface on which the panels are disposed faces each other. Alternatively, the elastic member 1000 can be bent so that an opposite surface of the surface on which the panels are disposed faces each other.

Hereinafter, the elastic member will be described as being bent in a direction such that the first surface 1S faces each other. Furthermore, the first surface 1S is defined as a surface on which the panel is disposed.

The elastic member 1000 includes a first region 1A and a second region 2A. The first region 1A and the second region 2A are regions defined when the elastic member 1000 is bent.

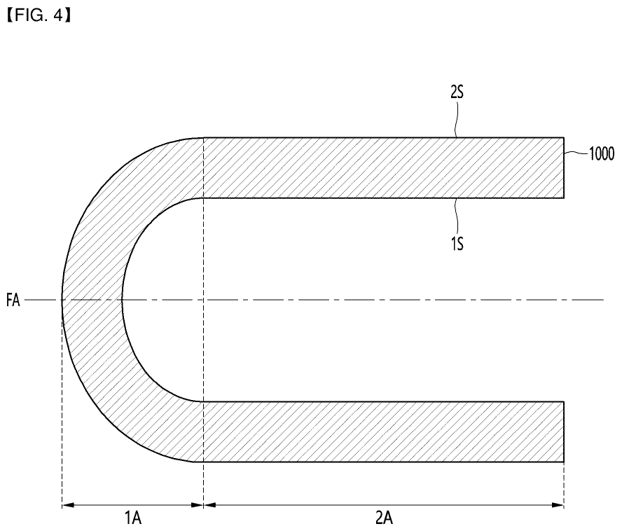

Referring to FIGS. 3 and 4, the elastic member 1000 includes a first region 1A that is bent. In addition, the elastic member 1000 includes a second region 2A that is not bent.

The second region 2A may be formed on left and right sides of the first region 1A, respectively. That is, the second region 2A may be disposed at both ends of the first region 1A. That is, the first region 1A may be disposed between the second region 2A.

However, the embodiment is not limited thereto. For example, the first region 1A may be further formed outside the second region 2A.

Sizes of the first region 1A and the second region 2A may be different. For example, an area of the second region 2A may be larger than that of the first region 1A.

For example, the area of the first region 1A may be 1% to 30% of a total area of the elastic member 1000. Specifically, the area of the first region 1A may be 5% to 20% of the total area of the elastic member 1000. More specifically, the area of the first region 1A may be 10% to 15% of the total area of the elastic member 1000.

If the area of the first region 1A is less than 1% of the total area of the elastic member 1000, cracks may occur at an interface between the folding region and the unfolding region of the elastic member. Accordingly, the folding reliability of the elastic member 1000 may be reduced.

Furthermore, if the area of the first region 1A exceeds 30% of the total area of the elastic member 1000, curling may occur in the first region 1A when folding the elastic member.

In FIGS. 3 and 4, the first region 1A is illustrated as being located at a center of the elastic member 1000. However, the embodiment is not limited thereto. For example, the first region 1A may be located at one end and another end regions of the elastic member 1000.

Referring to FIG. 4, the elastic member 1000 is bent in one direction with respect to the folding axis. Specifically, the elastic member 1000 is folded along the folding axis in a direction in which the first surface 1S faces each other.

The first region 1A may be defined as a region in which a curvature (R) is formed. In addition, the second region 2A may be defined as a region in which no curvature (R) is formed. Alternatively, the second region 2A may be defined as a region in which a curvature is close to 0.

A plurality of pattern parts may be formed in at least one of the first region 1A and the second region 2A. The pattern parts will be described below.

The elastic member 1000 includes a plurality of layers.

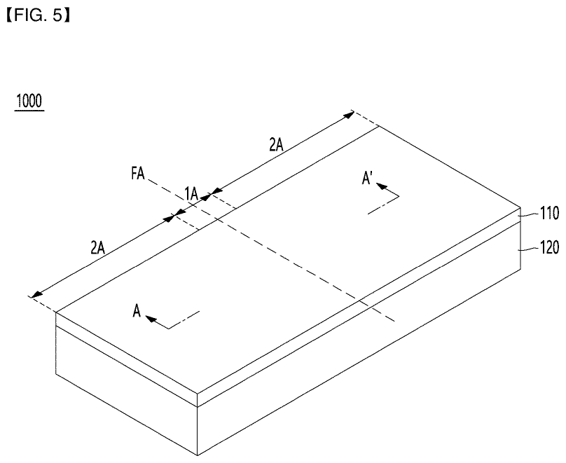

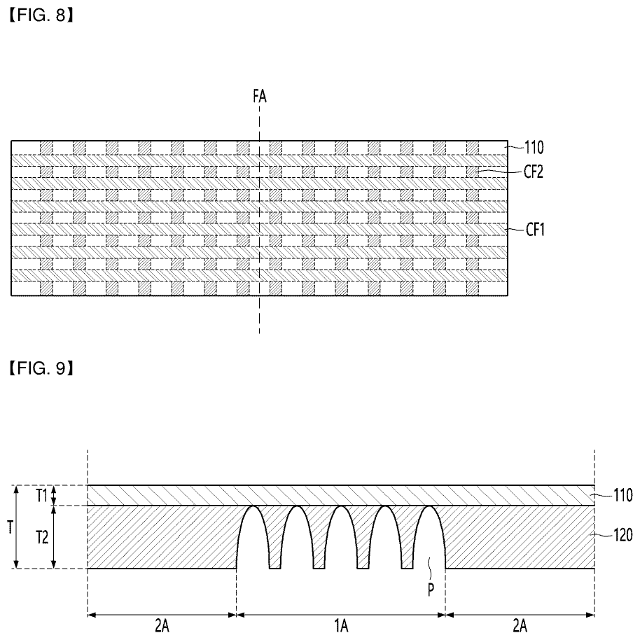

Hereinafter, an elastic member according to a first embodiment will be described with reference to FIGS. 5 to 18.

Referring to FIGS. 5 to 18, the elastic member 1000 according to the first embodiment includes a first layer 110 and a second layer 120. The second layer 120 may be disposed on the first layer 110.

The first layer 110 and the second layer 120 include a base material 150 and fibers. Specifically, the first layer 110 includes the base material 150 and a first fiber CF1 disposed within the base material 150. The second layer 120 includes the base material 150 and a second fiber CF2 disposed within the base material 150.

The base material 150 accommodates the fibers CF1 and CF2. The base material 150 supports the fibers CF1 and CF2.

The base material 150 may include a resin material. For example, the base material 150 may include at least one resin material selected from a group consisting of polyimide, polysulfone, polyphenylene sulfide, polyamide-imide, polyether ether ketone, liquid-crystal polyester, polyamide, polyoxymethylene, polycarbonate, polybutylene terephthalate, modified polyphenylene oxide, epoxy, and acrylate.

The fibers CF1 and CF2 are disposed in the base material 150. For example, the fibers CF1 and CF2 may be impregnated into the base material 150.

The fibers CF1 and CF2 may include an elastic material. For example, the fibers CF1 and CF2 may include at least one of carbon fiber, glass fiber, and ceramic fiber. Preferably, the fibers CF1 and CF2 include carbon fiber.

The fibers CF1 and CF2 may have a set length and a set diameter. For example, the fibers CF1 and CF2 may have a diameter of 0.0001 mm to 0.01 mm. In addition, the lengths of the fibers CF1 and CF2 may vary depending on a size of the base material 150.

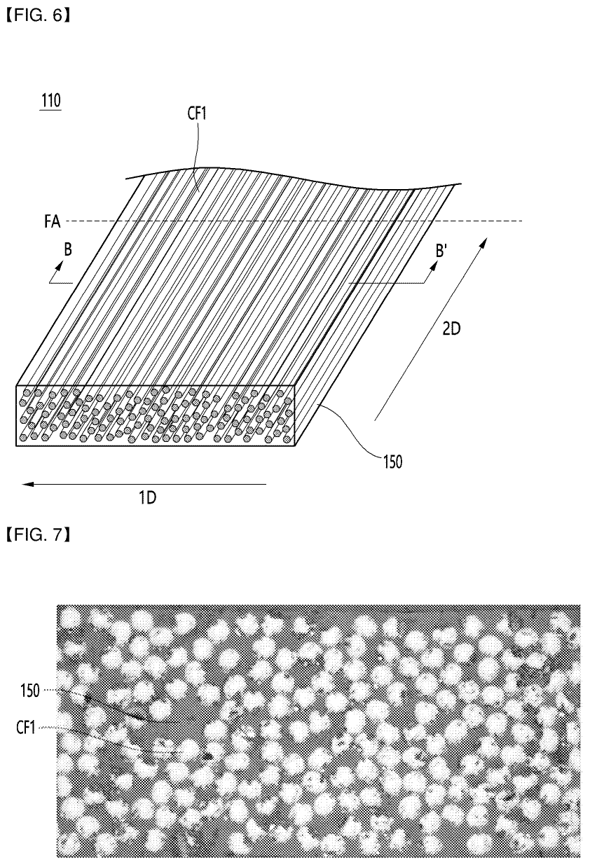

Referring to FIGS. 6 to 8, the fibers extend in one direction. The first fiber CF1 and the second fiber CF2 extend in different directions.

The first fiber CF1 extends in a different direction from the folding axis FA. The first fiber CF1 extends in a folding direction of the elastic member 1000. The first fiber CF1 extends in a direction perpendicular to the folding axis FA. For example, the first fiber CF1 extends at an angle of 80° to 100° with respect to the folding axis FA. Specifically, the first layer 110 includes the base material 150 and a plurality of first fibers. In addition, the plurality of first fibers extend at an angle of 80° to 100° with respect to the folding axis FA.

The second fiber CF2 extends in a direction identical to or similar to the folding axis FA. The second fiber CF2 extends in a direction opposite to the folding direction of the elastic member 1000. For example, the second fiber CF2 extends at an angle of 0° to 10° with respect to the folding axis FA. Specifically, the second layer 120 includes the base material 150 and a plurality of second fibers. In addition, the plurality of second fibers extend at an angle of 0° to 10° with respect to the folding axis FA.

A strength of the elastic member 1000 is enhanced by the first fiber CF1 and the second fiber CF2. The first fiber CF1 and the second fiber CF2 extend in different directions. That is, the first fiber CF1 and the second fiber CF2 extend in intersecting directions. Accordingly, the second region 2A is fixed by the first fiber CF1 and the second fiber CF2. Therefore, it is possible to prevent the shape of the second region above from changing when an external impact or elastic member is folded and unfolded.

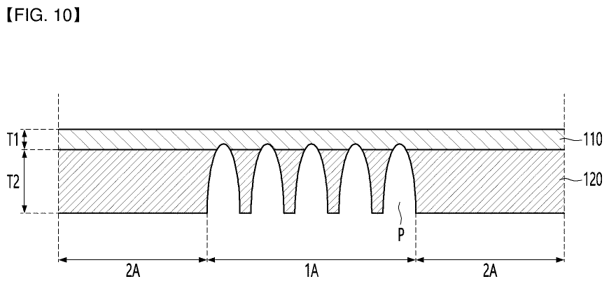

Referring to FIGS. 9 and 10, the elastic member 1000 includes a pattern part P. Specifically, the second layer 120 includes the pattern part P. The pattern part P is formed in a hole shape. Referring to FIG. 9, the pattern part P is formed by penetrating the second layer 120. Alternatively, referring to FIG. 10, the pattern part P penetrates the second layer 120 and partially penetrates the first layer 110. That is, depending on a process of forming the pattern part P, the pattern part P may be formed in the second layer 120 or both the first layer 110 and the second layer 120.

The pattern part P is formed in the first region 1A. That is, the pattern part P is formed in the folding region of the elastic member 1000. The second fiber CF2 is cut by the pattern part P. Specifically, the second fiber CF2 disposed in the first region 1A is cut. Specifically, the second fiber CF2 disposed in the folding region is cut.

Therefore, the elastic member 1000 can be folded with respect to the folding axis FA. Specifically, the first fiber CF1 extends in a direction perpendicular to or nearly perpendicular to the folding axis FA. In addition, the second fiber CF2 extends in a direction identical to or similar to the folding axis FA, and the second fiber CF2 of the first region 1A is cut. Therefore, when the elastic member 1000 is folded, it is not interfered with by the second fiber CF2.

Therefore, the elastic member 1000 can be easily bent in one direction by the pattern part P.

Meanwhile, the first fiber CF1 is not cut in the first region 1A. That is, the first fiber CF1 remains in the first region 1A. Accordingly, the elastic member 1000 can be easily restored by the first fiber CF1 after being bent.

The first layer 110 and the second layer 120 have different thicknesses. Specifically, the thickness T1 of the first layer 110 is smaller than the thickness T2 of the second layer 120. Since the thickness T of the first layer 110 in which the pattern part P is not formed is small, the elastic member is easily folded.

The thickness T of the elastic member 1000 may be 120 μm or less. Specifically, the thickness T of the elastic member 1000 may be 100 μm to 120 μm.

For example, the thickness T1 of the first layer 110 may be 5% or more of the thickness T of the elastic member 1000. Specifically, the thickness T1 of the first layer 110 may be 5% to 30% of the thickness T of the elastic member 1000. If the thickness T1 of the first layer 110 is less than 5% of the thickness T of the elastic member 1000, the thickness of the first layer 110 becomes thin. Accordingly, when forming the pattern part P, the first layer 110 may be penetrated together. Accordingly, the first fiber CF1 may be cut. Accordingly, the strength of the elastic member may be reduced. In addition, when folding the elastic member, a crease may be formed in the first region.

In addition, if the thickness T1 of the first layer 110 exceeds 30% of the thickness T of the elastic member 1000, the thickness of the first layer where the pattern part is not formed increases. Consequently, the folding characteristics of the elastic member 1000 may decrease.

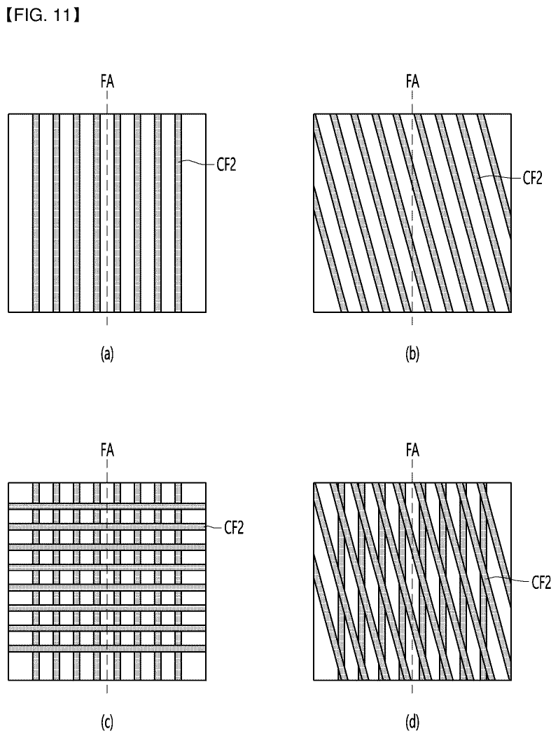

The second fiber CF2 extends in a different direction from the first fiber CF2. Referring to FIG. 11, the second fiber CF2 may extend in various directions.

Referring to (a) of FIG. 11, the second fiber CF2 may extend in a direction identical to or similar to the folding axis FA. For example, the second fiber CF2 may extend at an angle of 0° to 10° with respect to the folding axis FA.

Referring to (b) of FIG. 11, the second fiber CF2 may extend at an angle in a diagonal direction with respect to the folding axis FA. For example, the second fiber CF2 may extend at an angle of 30° to 60° with the folding axis FA.

Referring to (c) and (d) of FIG. 11, the second fiber CF2 may extend in a plurality of directions.

Referring to (c) of FIG. 11, at least one of the plurality of second fibers CF2 may extend in a direction identical to or similar to the folding axis. In addition, at least one of the plurality of second fibers CF2 may extend in a direction perpendicular to the folding axis. Accordingly, the second fiber CF2 may include a plurality of fibers that are orthogonal to each other.

Referring to (d) of FIG. 11, at least one of the plurality of second fibers CF2 may extend in a direction identical to or similar to the folding axis. Furthermore, at least one of the plurality of second fibers CF2 may extend at an angle in a diagonal direction with respect to the folding axis. Accordingly, the second fiber CF2 may include a plurality of fibers intersecting each other.

Alternatively, although not shown in the drawing, at least one of the plurality of second fibers CF2 may extend in a direction perpendicular to the folding axis. Furthermore, at least one of the plurality of second fibers CF2 may extend at an angle in a diagonal direction with respect to the folding axis. Accordingly, the second fiber CF2 may include a plurality of fibers intersecting each other.

The second layer 120 includes a plurality of pattern parts P. The pattern parts P penetrate the second layer 120. That is, the pattern part P may be formed in a hole shape penetrating the second layer 120.

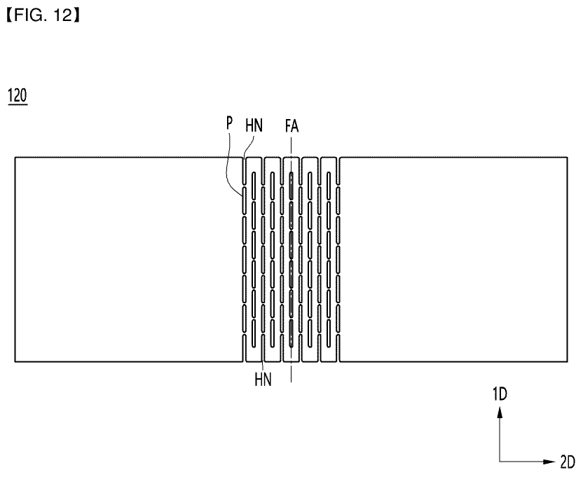

Referring to FIGS. 12 to 18, the pattern part P may be formed in various shapes.

Referring to FIG. 12, the second layer 120 may include a plurality of pattern parts P and a plurality of hinge parts HN. The pattern parts P may be spaced apart from each other in the first direction 1D and the second direction 2D. In addition, the hinge parts HN are disposed at ends of the second layer 120. Specifically, the hinge parts HN are formed by penetrating ends of the second layer 120 facing each other in the first direction 1D.

The second layer 120 includes a plurality of pattern parts spaced apart from each other. Therefore, a region where the pattern parts are not formed may increase. Accordingly, when folding and unfolding the elastic member 1000, creases can be prevented from occurring in the first region 1A.

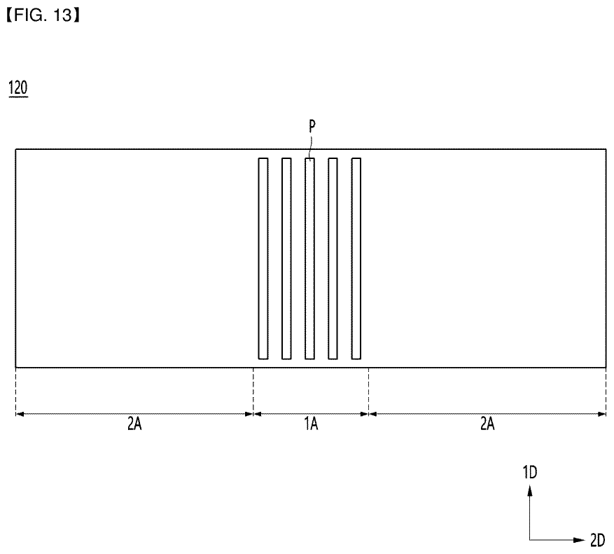

Referring to FIG. 13, the second layer 120 may include a plurality of pattern parts P. The pattern parts P extend in the first direction 1D. In addition, the plurality of pattern parts extend in the second direction. The pattern parts P are spaced apart from the ends of the second layer 120. Specifically, the pattern parts P are spaced apart from the ends of the second layer 120 that face each other in the first direction 1D.

The second layer 120 includes a plurality of pattern parts extending in the first direction 1D. Therefore, most of the second fiber CF2 disposed in the first region 1A can be cut. Accordingly, the folding characteristics of the elastic member can be improved. In addition, the pattern part is spaced apart from the end of the second layer. Therefore, a contact area between the first layer and the second layer increases. Accordingly, the adhesive characteristics of the first layer and the second layer are improved.

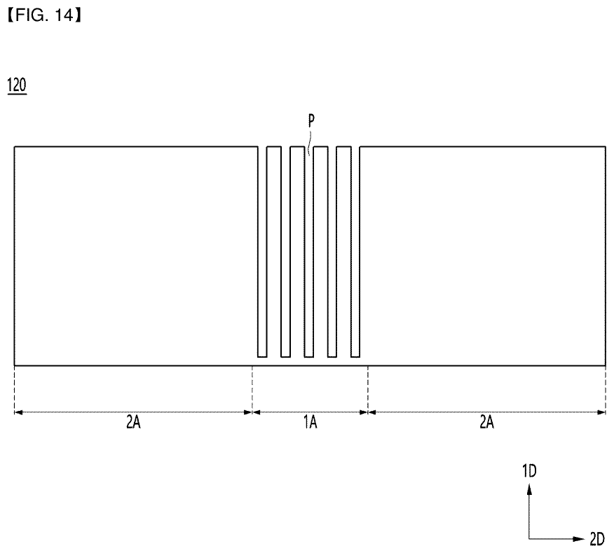

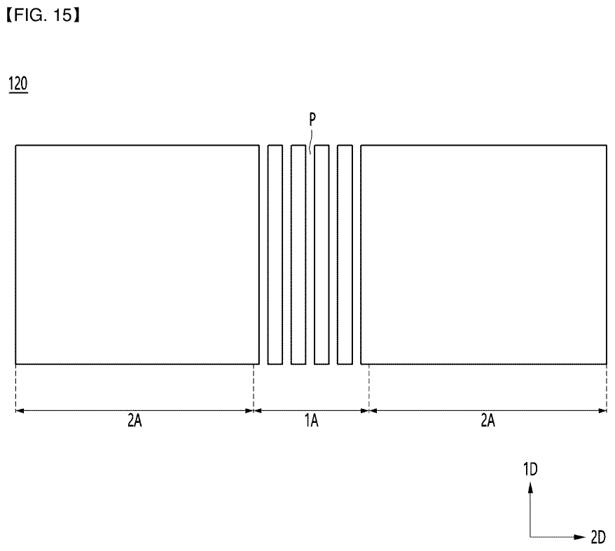

Referring to FIGS. 14 and 15, the second layer 120 may include a plurality of pattern parts P. The pattern part P extends in the first direction 1D. In addition, the plurality of pattern parts extend in the second direction. Referring to FIG. 14, the pattern part P is spaced apart from the end of the second layer 120. Specifically, the pattern part P is spaced apart from one of the ends of the second layer 120 facing in the first direction 1D. In addition, the pattern part P penetrates another end of the second layer 120 facing in the first direction 1D. Referring to FIG. 15, the pattern part P penetrates the end of the second layer 120. Specifically, the pattern part P penetrates the ends of the second layer 120 facing in the first direction 1D.

The second layer 120 includes a plurality of pattern parts extending in the first direction 1D. Therefore, most of the second fiber CF2 disposed in the first region 1A can be cut. Accordingly, the folding characteristics of the elastic member can be improved.

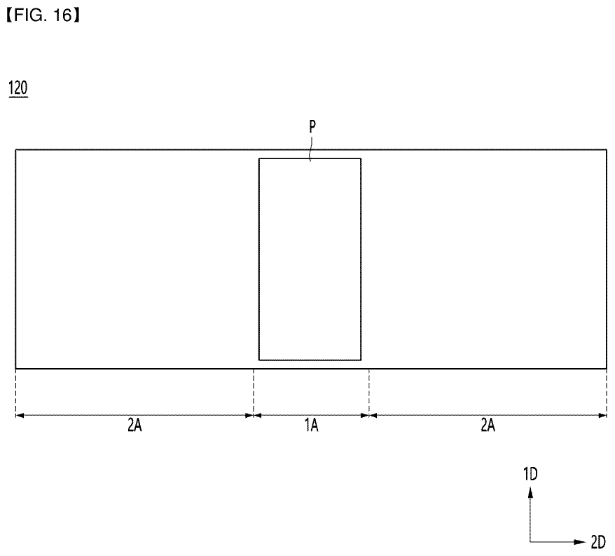

Referring to FIG. 16, the second layer 120 may include the pattern part P. The pattern part P is formed with a set area. The pattern part P is formed to have an area smaller than that of the first region 1A. Specifically, the pattern part P is formed to have an area of 50% to less than 100%, 60% to less than 100%, 70% to less than 100%, 80% to less than 100%, or 90% to less than 100% of the area of the first region 1A.

The pattern part P is spaced apart from the end of the second layer 120. Specifically, the pattern part P is spaced apart from the end of the second layer 120 facing in the first direction 1D.

The second layer 120 includes one pattern part having a set area. Therefore, most of the second fiber CF2 disposed in the first region 1A can be cut. Accordingly, the folding characteristics of the elastic member can be improved. In addition, the second layer 120 includes a region where a pattern part is not formed. Therefore, the contact area between the first layer and the second layer increases. Accordingly, the adhesive characteristics of the first layer and the second layer are improved.

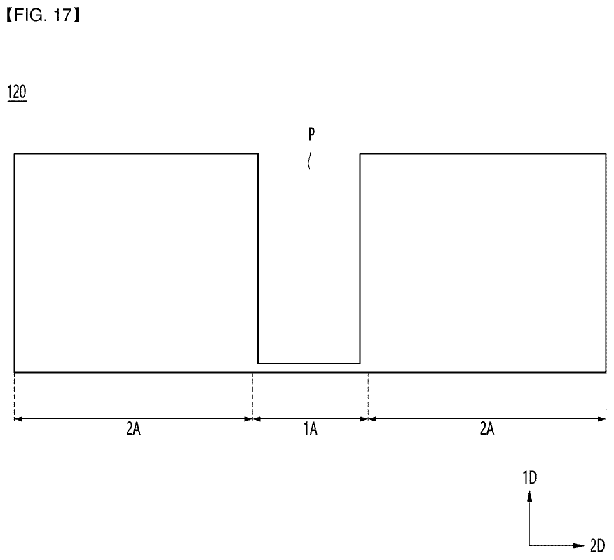

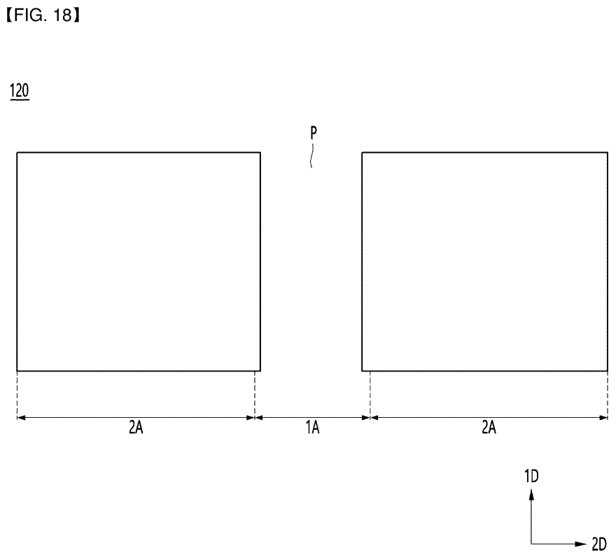

Referring to FIGS. 17 and 18, the second layer 120 may include one pattern part having a set area. The pattern part P is formed to have a smaller area than the first region 1A. Referring to FIG. 17, the pattern part P is formed to have an area of 60% to less than 100%, 70% to less than 100%, 80% to less than 100%, or 90% to less than 100% of the area of the first region 1A.

Referring to FIG. 17, the pattern part P is spaced apart from an end of the second layer 120. Specifically, the pattern part P is spaced apart from one of the ends of the second layer 120 facing in the first direction 1D. In addition, the pattern part P penetrates another end of the second layer 120 facing in the first direction 1D. Referring to FIG. 18, the pattern part P penetrates the end of the second layer 120. Specifically, the pattern part P penetrates the ends of the second layer 120 facing in the first direction 1D.

The second layer 120 includes one pattern part having a set area. Therefore, most of the second fiber CF2 disposed in the first region 1A can be cut. Accordingly, the folding characteristics of the elastic member can be improved. In addition, the second layer 120 includes a region where the pattern part is not formed. Therefore, the contact area between the first layer and the second layer increases. Accordingly, the adhesive characteristics of the first layer and the second layer are improved.

An elastic member according to a first embodiment includes a first layer and a second layer. The first layer includes a first fiber, and the second layer includes a second fiber.

The first fiber and the second fiber extend in different directions. Therefore, the first fiber and the second fiber are disposed in an intersecting manner. This enhances the strength of the elastic member. Accordingly, the folding reliability of the elastic member is improved. When the elastic member is folded and then unfolded, stress can be transmitted to the second region Accordingly, a shape of the second region can be changed. The elastic member according to the first embodiment includes fibers extending in different directions. Therefore, the shape of the second region can be prevented from changing due to the stress. Therefore, the elastic member according to the first embodiment has improved folding reliability.

Furthermore, fibers extending in a direction different from a direction in which the folding axis extends are cut. Specifically, the second fiber is cut at the first region. Therefore, the elastic member is easily folded at the first region. Therefore, the elastic member according to the first embodiment has improved folding characteristics.

Furthermore, the thickness of the elastic member according to the first embodiment is reduced. Specifically, the elastic member does not require a separate metal plate for enhanced strength. Therefore, since the thickness of the elastic member is reduced, the thickness of the display device is also reduced, and the folding characteristics of the display device are improved.

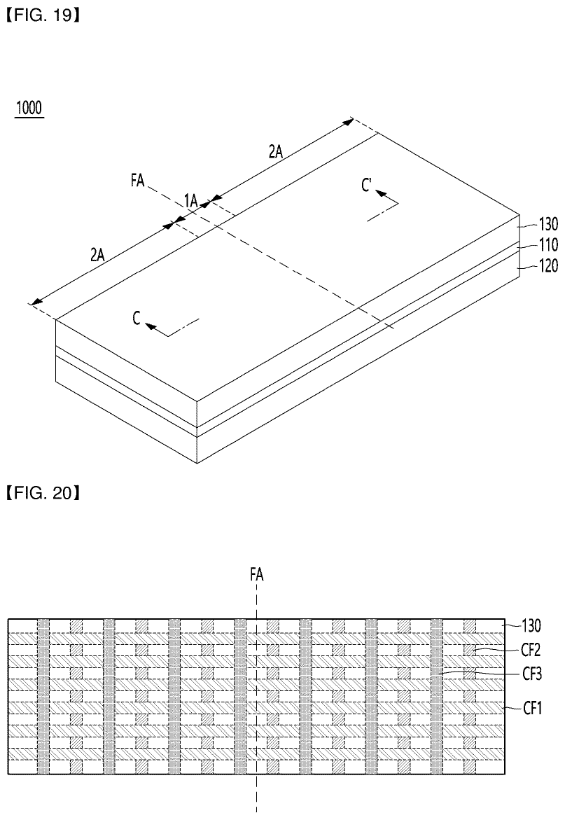

Hereinafter, an elastic member according to the second embodiment will be described with reference to FIGS. 19 to 25. A description identical to that of the first embodiment will be omitted. Furthermore, identical or similar components to those of the first embodiment are designated by the same reference numerals.

Referring to FIGS. 19 to 25, the elastic member 1000 according to the second embodiment includes a first layer 110, a second layer 120, and a third layer 130. The second layer 120 is disposed below the first layer 110. The third layer 130 is disposed above the first layer 110. Therefore, the first layer 110 is disposed between the second layer 120 and the third layer 130.

The first layer 110, the second layer 120, and the third layer 130 include a base material 150 and fibers. Specifically, the first layer 110 includes the base material 150 and a first fiber CF1 disposed in the base material 150. The second layer 120 includes the base material 150 and a second fiber CF2 disposed in the base material 150. The third layer 130 includes the base material 150 and a third fiber CF3 disposed in the base material 150.

The base material 150 accommodates the fibers CF1, CF2, and CF3. The base material 150 supports the fibers CF1, CF2, and CF3.

The material of the base material 150 is the same as in the first embodiment, and thus, a detailed description thereof will be omitted.

The fibers CF1, CF2, and CF3 are disposed in the base material 150. For example, the fibers CF1, CF2, and CF3 may be impregnated in the base material 150.

The material and size of the fibers CF1, CF2, and CF3 are the same as in the first embodiment, and thus, a detailed description thereof will be omitted.

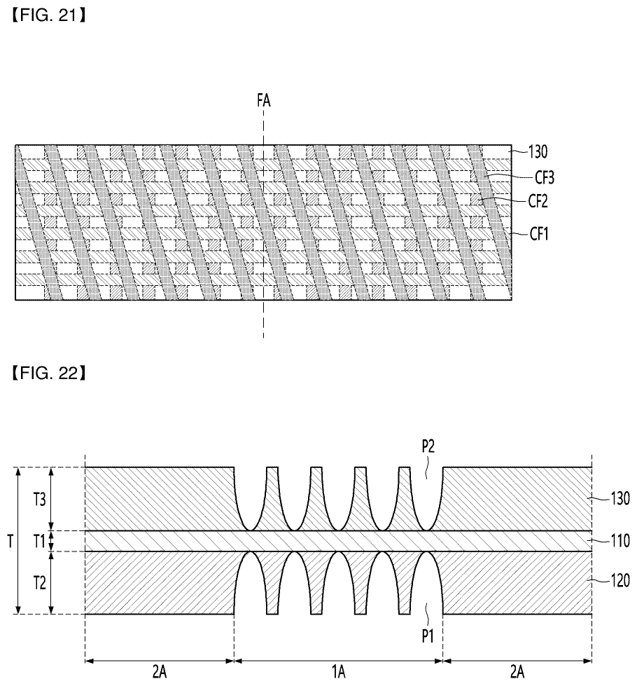

The fibers extend in one direction. Referring to FIGS. 20 and 21, one of the first fiber CF1, the second fiber CF2, and the third fiber CF3 extends in a different direction from the other fibers.

Referring to FIG. 20, the first fiber CF1 extends in a different direction from the second fiber CF2 and the third fiber CF3.

The first fiber CF1 extends in a different direction from the folding axis FA. The first fiber CF1 extends in the folding direction of the elastic member 1000. The first fiber CF1 extends in a direction perpendicular to the folding axis FA. For example, the first fiber CF1 extends at an angle of 80° to 100° with respect to the folding axis FA. In detail, the first layer 110 includes the base material 150 and a plurality of first fibers. In addition, the plurality of first fibers extend at an angle of 80° to 100° with respect to the folding axis FA.

The second fiber CF2 and the third fiber CF3 extend in the same or similar direction as the folding axis FA. The second fiber CF2 and the third fiber CF3 extend in the folding direction of the elastic member 1000. For example, the second fiber CF2 and the third fiber CF3 extend at an angle of 0° to 10° with respect to the folding axis FA. In detail, the second layer 120 includes the base material 150 and a plurality of second fibers. In addition, the plurality of second fibers extend at an angle of 0° to 10° with respect to the folding axis FA. In addition, the third layer 130 includes the base material 150 and a plurality of third fibers. In addition, the plurality of third fibers extend at an angle of 0° to 10° with respect to the folding axis FA.

Referring to FIG. 21, the first fiber CF1, the second fiber CF2, and the third fiber CF3 extend in different directions.

The first fiber CF1 extends in a different direction from the folding axis FA. The first fiber CF1 extends in the folding direction of the elastic member 1000. The first fiber CF1 extends in a direction perpendicular to the folding axis FA. For example, the first fiber CF1 extends at an angle of 80° to 100° with respect to the folding axis FA. In detail, the first layer 110 includes the base material 150 and a plurality of first fibers. In addition, the plurality of first fibers extend at an angle of 80° to 100° with respect to the folding axis FA.

The second fiber CF2 extends in a direction identical to or similar to the folding axis FA. The second fiber CF2 extends in the folding direction of the elastic member 1000. For example, the second fiber CF2 extends at an angle of 0° to 10° with respect to the folding axis FA. Specifically, the second layer 120 includes the base material 150 and a plurality of second fibers. Furthermore, the plurality of second fibers extend at an angle of 0° to 10° with respect to the folding axis FA.

The third fiber CF3 may extend at an angle in a diagonal direction with respect to the folding axis FA. For example, the third fiber CF3 may extend at an angle of 30° to 60° with respect to the folding axis FA. Specifically, the third layer 130 includes the base material 150 and a plurality of third fibers. Furthermore, the plurality of third fibers extend at an angle of 30° to 60° with respect to the folding axis FA.

However, the embodiment is not limited thereto. The second fiber CF2 and the third fiber CF3 may extend in various directions or multiple directions, as illustrated in FIG. 11.

The strength of the elastic member 1000 is enhanced by the first fiber CF1, the second fiber CF2, and the third fiber CF3. The first fiber CF1 extends in a different direction from the second fiber CF2 and the third fiber CF3. That is, the first fiber CF1 extends in a direction that intersects a direction in which the second fiber CF2 and the third fiber CF3 extend. Accordingly, the second region 2A is fixed by the first fiber CF1, the second fiber CF2, and the third fiber CF3. Therefore, the shape of the second region can be prevented from changing when subjected to an external impact or when the elastic member is folded and unfolded.

Referring to FIGS. 22 to 25, the elastic member 1000 includes a pattern part P. Specifically, the second layer 120 includes a first pattern part P1. Furthermore, the third layer 130 includes a second pattern part P2. The pattern part P is formed in a hole shape. Referring to FIG. 22, the first pattern part P1 is formed by penetrating the second layer 120. Furthermore, the second pattern part P2 is formed by penetrating the third layer 130.

Alternatively, referring to FIG. 23, the first pattern part P1 penetrates the second layer 120 and partially penetrates the first layer 110. In addition, the second pattern part P2 penetrates the third layer 130 and partially penetrates the first layer 110. That is, depending on the process of forming the pattern parts P1 and P2, the pattern parts P1 and P2 may be formed in the second layer 120 and the third layer 130, or may be formed in all of the first layer 110, the second layer 120, and the third layer 130.

The first pattern part P1 and the second pattern part P2 may be formed in various shapes. In detail, the first pattern part P1 and the second pattern part P2 may be formed in various shapes as shown in FIGS. 12 to 18.

The first pattern part P1 and the second pattern part P2 are formed in the first region 1A. That is, the first pattern part P1 and the second pattern part P2 are formed in the folding region of the elastic member 1000. The second fiber CF2 is cut by the first pattern part P1. Specifically, the second fiber CF2 disposed in the first region 1A is cut. Specifically, the second fiber CF2 disposed in the folding region is cut. In addition, the third fiber CF3 is cut by the second pattern part P2. Specifically, the third fiber CF3 disposed in the first region 1A is cut. Specifically, the third fiber CF3 disposed in the folding region is cut.

Accordingly, the elastic member 1000 can be folded about the folding axis FA. Specifically, the first fiber CF1 extends in a direction perpendicular or nearly perpendicular to the folding axis FA. Furthermore, the second fiber CF2 and the third fiber CF3 extend in the same, similar, or diagonal direction as the folding axis FA, and the second fiber CF2 and the third fiber CF3 of the first region 1A are cut. Therefore, when the elastic member 1000 is folded, it is not interfered with by the second fiber CF2.

Therefore, the elastic member 1000 can be easily bent in one direction by the first pattern part P1 and the second pattern part P2.

The first layer 110 has a different thickness from the second layer 120 and the third layer 130. Specifically, the thickness T1 of the first layer 110 is smaller than the thickness T2 of the second layer 120. Furthermore, the thickness T1 of the first layer 110 is smaller than the thickness T3 of the third layer 130. Since the thickness T of the first layer 110 where the pattern parts P1 and P2 are not formed is small, the elastic member is easily folded.

For example, the thickness T1 of the first layer 110 may be 5% or more of the thickness T of the elastic member 1000. Specifically, the thickness T1 of the first layer 110 may be 5% to 30% of the thickness T of the elastic member 1000. If the thickness T1 of the first layer 110 is less than 5% of the thickness T of the elastic member 1000, the thickness of the first layer 110 becomes thin. Accordingly, when forming the pattern parts P1 and P2, the first layer 110 may be penetrated together. Accordingly, the first fiber CF1 may be cut. Accordingly, the strength of the elastic member may be reduced. In addition, when folding the elastic member, a crease may be formed in the first region.

Additionally, if the thickness T1 of the first layer 110 exceeds 30% of the thickness T of the elastic member 1000, the thickness of the first layer where the pattern part is not formed increases. Consequently, the folding characteristics of the elastic member 1000 may decrease.

Referring to FIG. 24, the first pattern part P1 and the second pattern part P2 do not overlap. Specifically, the first pattern part P1 and the second pattern part P2 do not overlap in the thickness direction of the first layer 110. Accordingly, one or more second pattern parts are disposed between adjacent first pattern parts. Furthermore, one or more first pattern parts are disposed between adjacent second pattern parts.

Therefore, penetration of the first layer 110 can be prevented. An etchant that etches the second layer 120 and the third layer 130 can also etch the first layer 110. Accordingly, when etching the second layer 120 and the third layer 130, the first layer 110 can also be etched. As a result, a through hole can be formed in the first layer 110. As a result, the first fiber CF1 can be cut.

Since the first pattern part P1 and the second pattern part P2 are disposed so as not to overlap, the first layer 110 can be prevented from being penetrated. Since a center of the first pattern part P1 and a center of the second pattern part P2 are disposed so as not to overlap, the first layer 110 can be prevented from being penetrated. Alternatively, a region where the first layer 110 is partially penetrated by the first pattern part P1 and a region where the first layer 110 is partially penetrated by the second pattern part P2 do not meet. Accordingly, it is possible to prevent the through hole from being formed in the first layer 110.

Therefore, the elastic member according to the embodiment can have improved folding reliability. That is, when the elastic member is folded and unfolded, the first fiber can fix the first region. Thereby, it is possible to prevent wrinkles from being formed in the first region.

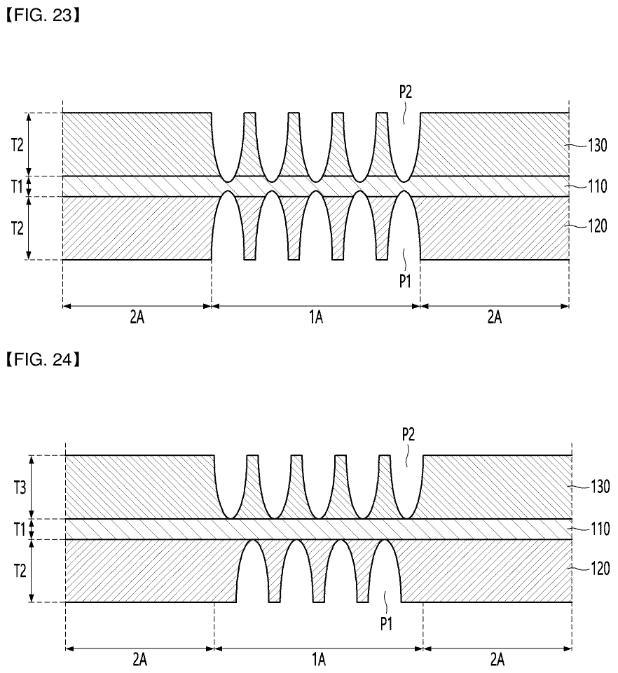

Referring to FIG. 25, the first pattern part P1 and the second pattern part P2 may be formed with different sizes. For example, the size of the first pattern part P1 may be smaller than that of the second pattern part P2. The size of the pattern part may be defined by a diameter or width of a surface hole. Alternatively, the size of the pattern part may be defined by an area of the pattern part.

Accordingly, the folding characteristics of the elastic member may be improved. Densities of the second fiber CF2 and the third fiber CF3 may differ. For example, the density of the second fiber CF2 may be lower than that of the third fiber CF3. Since the second pattern part P2 is formed to be large, the third fiber CF3 of the first region 1A can be easily cut. Accordingly, when folding the elastic member, it is possible to prevent the folding of the elastic member from interfering with the third fiber.

In addition, the visibility of the display device may be improved. The panel may be disposed on the second layer 120. Since the size of the first pattern part P1 is formed to be small, the pattern part can be prevented from being visible to an external user.

The elastic member according to the second embodiment includes a first layer, a second layer, and a third layer. The first layer includes a first fiber, the second layer includes a second fiber, and the third layer includes a third fiber.

The first fiber extends in a different direction from the second fiber and the third fiber. Alternatively, the first fiber, the second fiber, and the third fiber extend in different directions.

Therefore, the first fiber, the second fiber, and the third fiber are disposed in an intersecting manner. This enhances the strength of the elastic member. Accordingly, the folding reliability of the elastic member is enhanced. When the elastic member is folded and then unfolded, stress can be transmitted to the second region. Accordingly, a shape of the second region can be changed. The elastic member according to the second embodiment includes fibers extending in different directions. Accordingly, the shape of the second region can be prevented from changing due to the stress. Therefore, the elastic member according to the second embodiment has improved folding reliability.

Furthermore, the fibers extending in a direction different from a direction in which the folding axis extends are cut. Specifically, the second fiber and the third fiber are cut in the first region. Therefore, the elastic member can be easily folded in the first region. Therefore, the elastic member according to the second embodiment has improved folding characteristics.

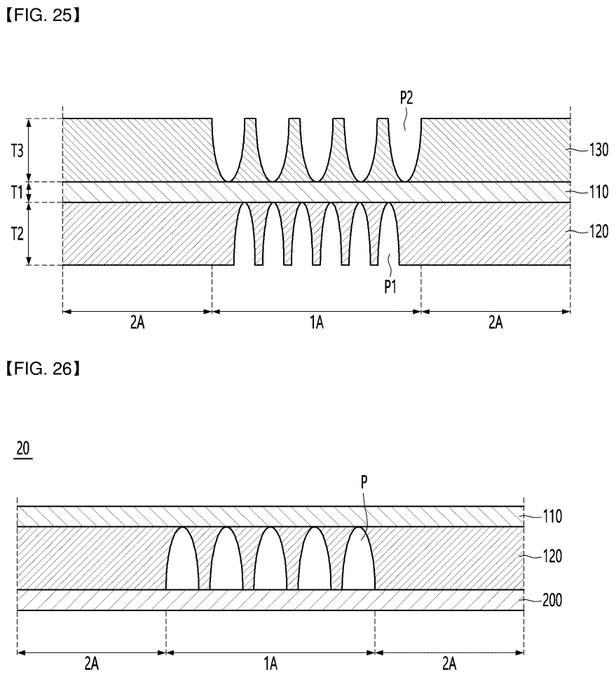

Hereinafter, a folding support 20 including an elastic member according to the embodiment will be described with reference to FIGS. 26 and 27.

Referring to FIGS. 26 and 27, the folding support 20 includes an elastic member 1000 and a protective layer 200.

The protective layer 200 is disposed below the elastic member 1000. For example, an adhesive layer is disposed between the protective layer 420 and the elastic member 1000. The elastic member 1000 and the protective layer 200 may be bonded by the adhesive layer.

The protective layer 200 may have a color. For example, the protective layer 200 may have a black color.

The protective layer 200 may include metal particles. For example, the protective layer 200 may include copper particles. Accordingly, the thermal conductivity of the protective layer 200 may be improved. Accordingly, heat generated in the display device may be dissipated by the protective layer 200.

The protective layer 200 may be disposed in a region corresponding to the first region 1A of the elastic member 1000. Alternatively, the protective layer 200 may be disposed in a region corresponding to the first region 1A and the second region 2A of the elastic member 1000.

For example, the protective layer 200 is disposed in a region corresponding to the first region 1A and the second region 2A of the elastic member 1000. The protective layer 200 may be disposed in an area smaller than a sum of areas of the first region 1A and the second region 2A. For example, the protective layer 200 may be disposed in an area that is 80% to 90% of the sum of the areas of the first region 1A and the second region 2A of the elastic member.

In addition, the thickness of the protective layer 200 may be smaller than the thickness of the elastic member 1000.

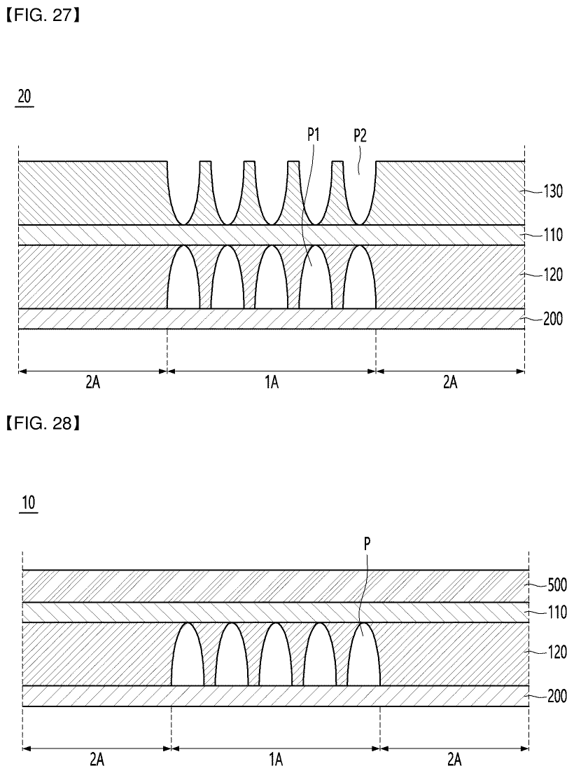

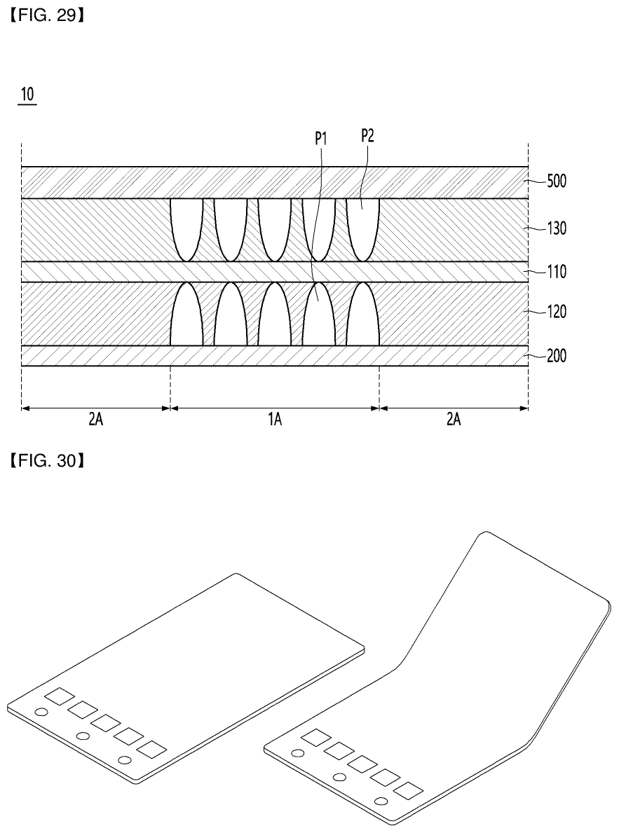

Hereinafter, a display device including a folding support according to an embodiment will be described with reference to FIGS. 28 and 29.

Referring to FIGS. 28 and 29, the display device 10 may include the folding support 20 and a panel layer 500.

The panel layer 500 may include at least one panel among the display panel and the touch panel.

An adhesive layer may be disposed between the folding support 20 and the panel layer 500. The folding support 20 and the panel layer 500 may be adhered by the adhesive layer.

Referring to FIG. 28, the panel layer 500 may be disposed on the first layer 110. That is, the panel layer 500 can be disposed on a layer where the pattern part is not formed.

Therefore, a separate planarization layer disposed between the folding support 20 and the panel layer 500 can be omitted. This reduces the thickness of the display device. Furthermore, the pattern part can be prevented from being viewed by an external user.

Referring to FIG. 29, the panel layer 500 can be disposed on the second layer 120 or the third layer 130. The sizes of the first pattern part P1 and the second pattern part P2 may differ. For example, the size of the second pattern part P2 may be smaller than the size of the first pattern part P1, and the panel layer 500 can be disposed on the third layer 130. Accordingly, the pattern part can be prevented from being viewed by an external user.

FIG. 30 is a drawing illustrating an example of applying an elastic member according to embodiments.

Referring to FIG. 30, the elastic member according to embodiments can be applied to a flexible or foldable display device that displays a display.

For example, the elastic member according to embodiments can be applied to a flexible display device, including a mobile phone or tablet. Thus, the display device can be bent or folded.

The display device can be easily folded by the elastic member. Furthermore, the folding reliability of the display device can be improved.

The characteristics, structures and effects described in the embodiments above are included in at least one embodiment but are not limited to one embodiment. Furthermore, the characteristics, structures, and effects and the like illustrated in each of the embodiments may be combined or modified even with respect to other embodiments by those of ordinary skill in the art to which the embodiments pertain. Thus, it should be construed that contents related to such a combination and such a modification are included in the scope of the embodiment.

The above description has been focused on the embodiment, but it is merely illustrative and does not limit the embodiment. A person skilled in the art to which the embodiment pertains may appreciate that various modifications and applications not illustrated above are possible without departing from the essential features of the embodiment. For example, each component particularly represented in the embodiment may be modified and implemented. In addition, it should be construed that differences related to such changes and applications are included in the scope of the embodiment defined in the appended claims.

1. An elastic member foldable with respect a folding axis, comprising:
a first layer including a first base material and a first fiber disposed in the first base material; and
a second layer disposed under the first layer and including a second base material and a second fiber disposed in the second base material,
wherein the second layer has a pattern part having a hole shape that penetrates upper and lower surfaces of the second laver,
wherein the first laver does not have a pattern portion having a hole shape,
wherein the first fiber and the second fiber extend in different directions, and
wherein a direction in which the second fiber extends is closer to a direction in which the folding axis extends than a direction in which the first fiber extends.

2-10. (canceled)

11. The elastic member of claim 1, wherein the first fiber extends in the first base material at an angle of 80° to 100° with respect to the folding axis.

12. The elastic member of claim 1, wherein the direction in which the second fiber extends has an angle of 0° to 10° with respect to the direction in which the folding axis extends in the second base material.

13. The elastic member of claim 1, wherein the direction in which the second fiber extends has an angle of 30°to 60°with respect to the direction in which the folding axis extends in the second base material.

14. The elastic member of claim 1, wherein the second fiber includes a plurality of fibers extending in different directions.

15. The elastic member of claim 14, wherein the second fiber includes a second-first fiber extending at an angle of 0° to 10° with respect to the direction in which the folding axis extends in the second base material; and a second-second fiber extending at an angle of 30° to 60° with respect to the direction in which the folding axis extends in the second base material.

16. The elastic member of claim 1, wherein the direction in which the first fiber extends and the direction in which the second fiber extends intersect each other.

17. The elastic member of claim 1, wherein the elastic member includes a first region closer to the folding axis and a second region disposed further from the folding axis than the first region, and
wherein the pattern part is provided in the first region.

18. The elastic member of claim 1, wherein the first layer includes a groove-shaped pattern part connected to the pattern part provided in the second layer.

19. The elastic member of claim 1, wherein a thickness of the first layer is smaller than a thickness of the second layer.

20. The elastic member of claim 1, further comprising:
a third layer disposed on of the first layer,
wherein the third layer includes a third base material and a third fiber provided in the third base material,
wherein the third fiber extends in a direction different from the direction in which the first fiber extends, and
wherein the third layer includes a pattern part with a hole-shape.

21. The elastic member of claim 20, wherein the direction in which the second fiber and the third fiber extend has an angle of 0° to 10° with respect to the direction in which the folding axis extends.

22. The elastic member of claim 20, wherein the second fiber and the third fiber extend at an angle of 30° to 60° with respect to the direction in which the folding axis extends.

23. The elastic member of claim 20, wherein at least one of the second fiber and the third fiber includes a first group of fibers extending at an angle of 0° to 10° with respect to the direction in which the folding axis extends, and a second group of fibers extending at an angle of 30° to 60° with respect to the direction in which the folding axis extends.

24. The elastic member of claim 20, wherein the second fiber and the third fiber extend in different directions.

25. The elastic member of claim 20, wherein the elastic member includes a first region and a second region,
wherein the first region is folded, and
wherein the pattern part of the second layer and the pattern part of the third layer are formed in the first region.

26. The elastic member of claim 20, wherein at least one of the pattern part of the second layer and the pattern part of the third layer is connected to a groove-shaped pattern part provided in the first layer.

27. The elastic member of claim 20, wherein the pattern part of the second layer and the pattern part of the third layer do not overlap in a thickness direction of the first layer.

28. The elastic member of claim 20, wherein the pattern part of the second layer and the pattern part of the third layer have different sizes.
